(19) United States
(12) Patent Application Publication
(10) Pub. No.: US 2025/0355344 A1
(43) Pub. Date: Nov. 20, 2025

(54) LITHOGRAPHY MASK HAVING OVERLAY MARK AND RELATED METHOD

(71) Applicant: Taiwan Semiconductor Manufacturing Co., Ltd., Hsinchu (TW)

(72) Inventors: Cheng-Yeh LEE, Hsinchu (TW); Ching-Fang YU, Hsinchu (TW); Hsueh-Wei HUANG, Hsinchu (TW); Yen-Cheng HO, Hsinchu (TW); Wei-Cheng LIN, Hsinchu (TW); Hsin-Yi YIN, Hsinchu (TW)

(73) Assignee: Taiwan Semiconductor Manufacturing Co., Ltd., Hsinchu (TW)

(21) Appl. No.: 19/290,038

(22) Filed: Aug. 4, 2025

Related U.S. Application Data
(63) Continuation of application No. 18/403,574, filed on Jan. 3, 2024.
(60) Provisional application No. 63/519,534, filed on Aug. 14, 2023.
(60) Provisional application No. 63/614,828, filed on Dec. 26, 2023.

(51) Int. Cl. G03F 1/42

(52) U.S. Cl. CPC G03F 1/42

(57) ABSTRACT

A method includes: generating a designed mask overlay mark associated with an actual mask overlay mark to be formed in a mask; forming the actual mask overlay mark in the mask based on the designed mask overlay mark, the actual mask overlay mark including a plurality of overlay patterns; forming a device feature pattern adjacent to the actual mask overlay mark; forming an alignment of the mask by a mask metrology apparatus including a light source having a wavelength and a numerical aperture, wherein a pitch between adjacent two of the plurality of overlay patterns does not exceed the wavelength divided by twice the numerical aperture; and forming a pattern in a layer of a wafer by transferring the device feature pattern while the mask is under the alignment.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagrammatic view depicting alignment of features of material layers on a semiconductor wafer according to embodiments of the present disclosure.

FIGS. 2A-2D are views of various embodiments of determining position of a mask overlay mark according to various aspects of the present disclosure.

FIG. 3 is a diagrammatic view of a mask overlay mark according to various aspects of the present disclosure.

FIG. 4 is a sequential view of use of a mask overlay mark according to various aspects of the present disclosure.

FIG. 5 is a diagrammatic view depicting in detail a region of a mask overlay mark in accordance with various embodiments.

FIGS. 6A-12E are diagrammatic views of overlay patterns and mask overlay marks in accordance with various embodiments.

FIG. 13 is a diagrammatic view of a mask metrology apparatus in accordance with various embodiments.

FIG. 14 is a flowchart of a method of forming an IC device in accordance with various embodiments.

FIGS. 15A and 15B are diagrammatic views of a mask in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

The present disclosure is generally related to methods of forming device features, such as semiconductor devices, interconnect structures (e.g., wires, traces, vias, plugs, contacts and the like), capacitors, memory devices, and the like. The semiconductor devices can include field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

Spacing and/or pitch scaling is increasingly difficult in advanced process nodes. Mask overlay is an index to show how precise positioning of a pattern is on a mask. A mask overlay mark is a pattern on the mask used to monitor mask overlay performance. Some mask overlay marks are or include isolated small squares having size in a range of hundreds of nanometers (nm), such as about 400 nm, which increases difficulty in setting a robust overlay measurement process. These small mask overlay patterns are still large enough that they are printed onto the wafer.

Embodiments of the disclosure provide a mask overlay mark that includes much smaller features with a combination of selected pitch or/and size. Based on these embodiments, individual features are resolvable for a mask making process and related tools but are beyond a resolution for mask overlay metrology tools. As such, contours of the individual features are detected by mask overlay metrology tools as a larger, solid feature. The individual features are also beyond a resolution for a wafer imaging process and related tools, so that the mask overlay mark is not printed on the wafer.

Using small features with a selected range of pitch or/and pitch combination(s) as the mask overlay mark achieves improved mask overlay reliability and repeatability performance and robust mask overlay measurement on the mask without pattern printing onto the wafer.

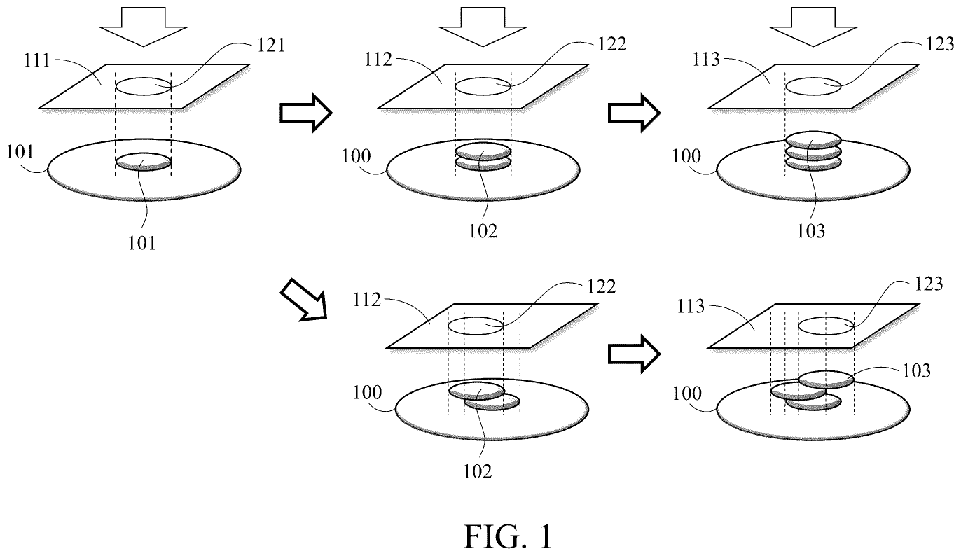

FIG. 1 is a diagrammatic view depicting alignment of features of material layers on a semiconductor wafer according to embodiments of the present disclosure. In FIG. 1, a semiconductor wafer 100 (or simply, “wafer 100”) is processed to form features 101, 102, 103 thereon. The features 101, 102, 103 may be additive features, such as dielectric layers, conductive layers, semiconductor layers, epitaxial layers and the like, and/or may be subtractive features, such as openings, trenches, grooves, holes and the like.

A first feature 101 is formed on the wafer 100 by directing first light carrying a first pattern 121 of a first mask 111 onto one or more layers (e.g., a photoresist) on or of the wafer 100. Following formation of the first feature 101, a top row of FIG. 1 depicts formation of subsequent second and third features 102, 103 that are aligned well with the first feature 101. A second feature 102 is formed on the first feature 101 by directing second light carrying a second pattern 122 of a second mask 112 onto one or more layers (e.g., a photoresist) on or of the wafer 100. The second feature 102 is aligned with the first feature 101, as indicated by dashed lines in FIG. 1. A third feature 103 is formed on the first and second features 101, 102 by directing third light carrying a third pattern 123 of a third mask 113 onto one or more layers (e.g., a photoresist) on or of the wafer 100. The third feature 103 is aligned with the second feature 102 and the first feature 101, as indicated by dashed lines in FIG. 1.

A bottom row of FIG. 1 depicts formation of the second and third features 102, 103 that are not aligned well with the first feature 101. For example, the second feature 102 may be offset from the first feature 101 toward the left of the page in FIG. 1. Then, the third feature 103 may be offset from the first and second features 101, 102 toward the right of the page in FIG. 1. This can result in multiple defects. For example, when forming an upper conductive feature on a lower conductive feature that is embedded in a dielectric layer, an opening in which the upper conductive feature is to be formed that is misaligned with the lower conductive feature may etch into the surrounding dielectric layer. When the upper conductive feature is formed, the upper conductive feature may land on the lower conductive feature, but may also extend into the dielectric layer below the lower conductive feature. This extension may lead to reduced time-dependent-dielectric-breakdown (TDDB), which can reduce lifespan of an integrated circuit (IC) device including the misaligned upper conductive feature. This is one example of a deleterious effect of misalignment between the first, second and third features 101, 102, 103. Other types of effects can also result from the misalignment, which may reduce circuit performance, increase defects which reduce yield, or the like.

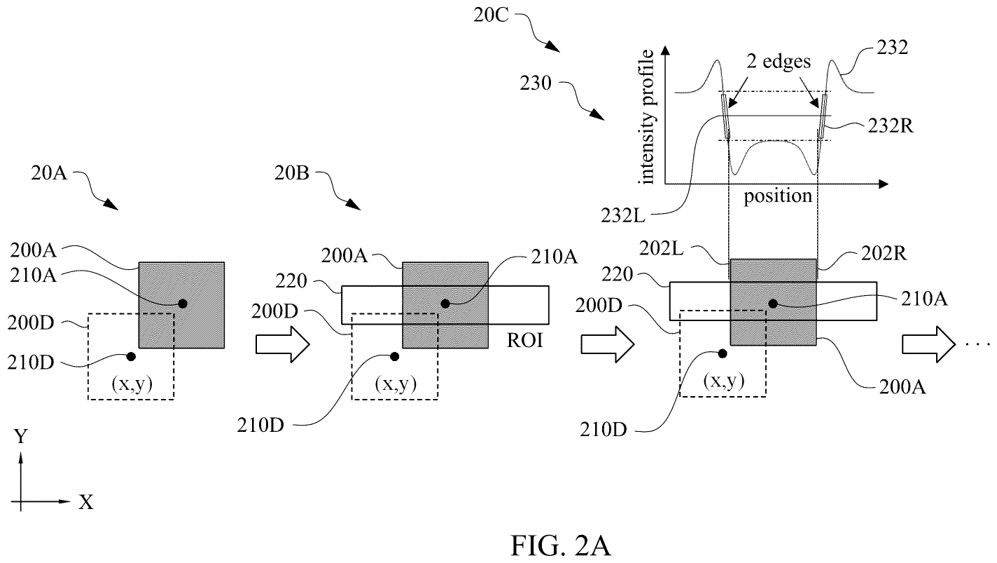

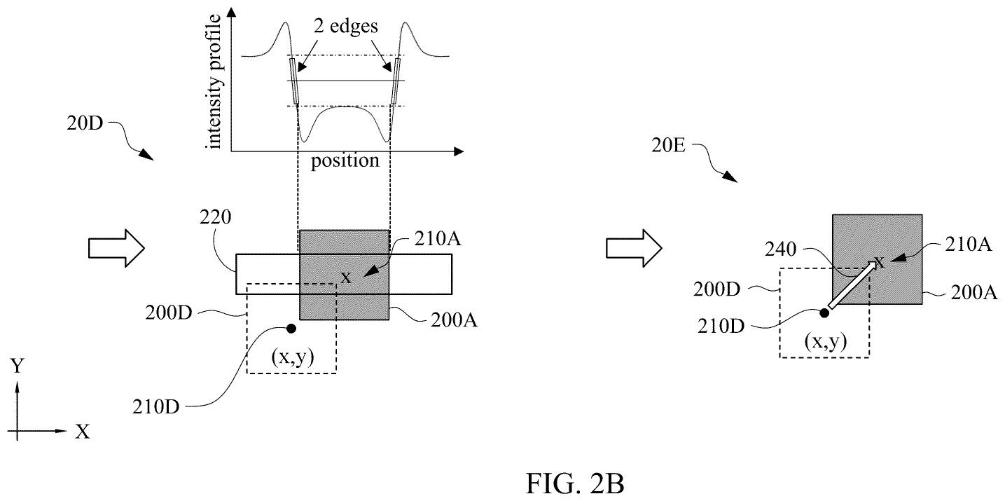

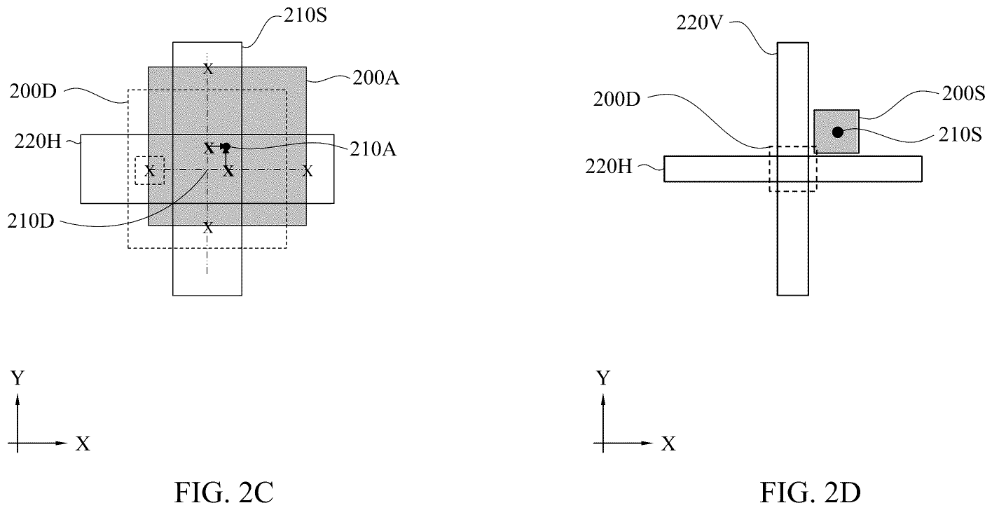

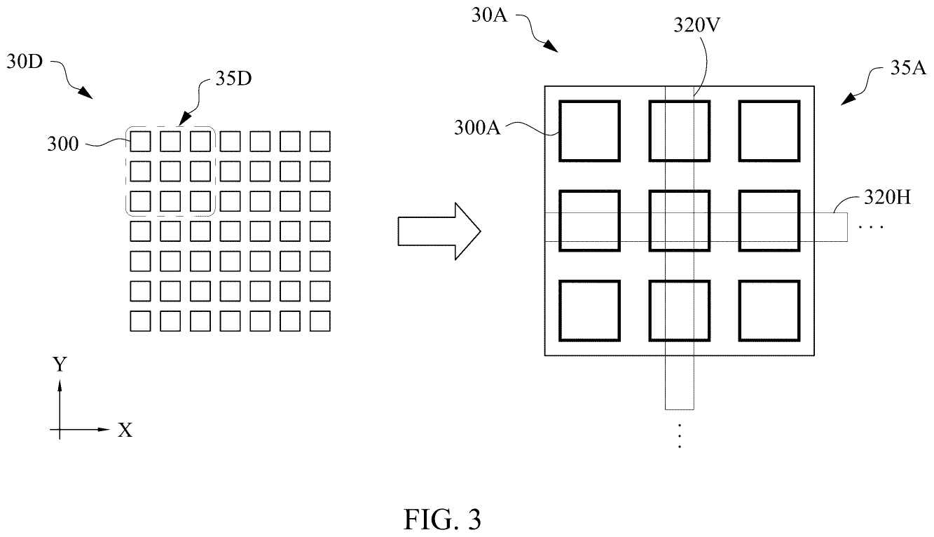

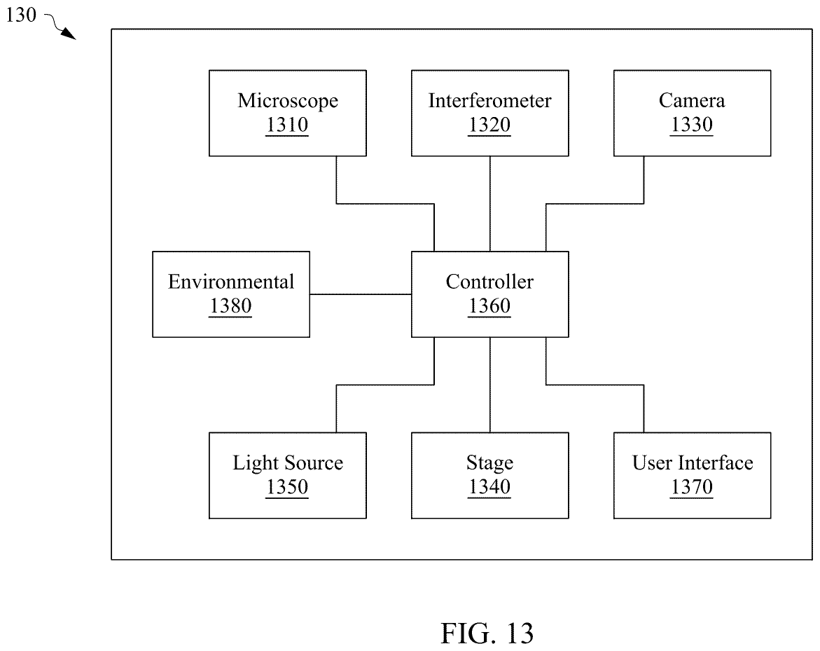

FIGS. 2A-2D are views of various embodiments of determining position of a mask overlay mark according to various aspects of the present disclosure. The position of a pattern, such as the mask overlay mark or a device feature pattern formed on the same mask as the mask overlay mark, may be determined by operation of a mask metrology apparatus. Example components and functions of a mask metrology apparatus 130 are described in detail in the following with reference to FIG. 13. The description provides context for understanding the embodiments of the disclosure that will be described with reference to FIGS. 3-12E and 14. One or more operations described with reference to FIGS. 2A-2D may be performed by the mask metrology apparatus 130 of FIG. 13.

The mask metrology apparatus 130 is operable to measure and verify dimensions, patterns and alignment of features on photomasks used in semiconductor fabrication. The accuracy of these measurements is beneficial for ensuring high yield and performance of the final semiconductor devices. In some embodiments, the mask metrology apparatus may include one or more of an optical microscope 1310, an interferometer 1320, camera and/or detector systems 1330, a stage(s) 1340, a light source 1350, a computational device or controller 1360, user interface 1370, environmental controls 1380 and the like. Some elements of the mask metrology apparatus 130 may be omitted from view in FIG. 13 for simplicity of illustration.

The optical microscope 1310 may be used to magnify features on the mask for visual inspection and measurement. High-resolution microscopes may be used for advanced nodes where features are extremely small. The interferometer 1320 may provide even higher accuracy, and interferometric methods can be used to measure dimensions and distances between features with increased precision. The camera and detector systems 1330 may include high-resolution cameras operable to capture images of mask features and alignment marks for analysis. The cameras can be grayscale or color cameras as beneficial to the mask metrology apparatus. The stage(s) 1340 can hold the mask and move the mask with high precision in X, Y, and Z directions as well as rotate the mask for complete inspection. The light source 1350 may be a highly stable, monochromatic light source that illuminates the mask. UV light sources are beneficial in mask metrology apparatuses used for advanced technology nodes. The computational unit or processor or controller 1360 may be operable to perform software algorithms that analyze images captured to measure feature sizes, distances and any misalignments. Machine learning may be used in the computational unit for more accurate and faster analysis. The controller 1360 may control operation of the various elements of the mask metrology apparatus 130, for example, via electrical signals. The user interface 1370 may include a display and/or control panel that allows operators to input parameters, control the mask metrology apparatus, and view results. Environmental controls 1380 may be operable to remove tiny contaminants or prevent temperature fluctuations that can affect measurements and may be built into the mask metrology apparatus 130.

Operations of the mask metrology apparatus 130 may include dimensional measurement, pattern verification, overlay accuracy, defect inspection, registration accuracy, data analysis, feedback for mask making, documentation and the like. During dimensional measurement, the width, height and other dimensions of the features on the mask may be measured and compared against design specifications. Pattern verification may confirm that the various shapes, lines, and structures on the mask are manufactured as designed. Overlay accuracy may use overlay marks, such that the mask metrology apparatus 130 can measure how accurately different layers of features on a multi-layer mask align with each other. Defect inspection may identify defects such as pinholes, cracks or misplaced features that can affect the semiconductor manufacturing process. Registration accuracy measures the precise position of alignment marks to ensure that the mask will properly align with the wafer during lithography. Data analysis can use data generated for quality control, mask qualification, and process optimization. The data can also be fed back to improve the mask-making process itself. The mask metrology apparatus 130 may also generate reports and logs for traceability, compliance and further analysis.

In FIG. 2A, in a first operation 20A, a designed pattern 200D that has box shape may be designed to be located at a position that may be associated with a center 210D at coordinates (x,y), depicted by a dashed line in FIG. 2A. An actual pattern 200A is present in a mask. The designed pattern 200D and the actual pattern 200A may each be referred to simply as a “pattern” throughout. The pattern 200A may be an overlay pattern or a device feature pattern. The pattern 200A is an actual pattern present in the mask. Namely, the pattern 200A may be a geometric shape that is present in a reflective layer or layers of the mask. Position of the pattern 200A within the mask may be unknown initially. For example, a center 210A of the pattern 200A may be unknown. The mask metrology apparatus may be used to determine the center 210A of the pattern 200A. For example, the mask metrology apparatus may determine the center 210A of the actual pattern 200A and/or may determine an offset of the center 210A of the actual pattern 200A from the center 210D of the designed pattern 200D.

In a second operation 20B, a region of interest (ROI) 220 may be selected to overlap the actual pattern 200A to capture edges of the actual pattern 200A. In the example depicted in FIG. 2A, the ROI 220 may be selected to capture edges associated with the “x” coordinate of the center 210A. In most embodiments, two ROIs are used, vertical and horizontal, to capture edges associated with the “x” coordinate and the “y” coordinate of the center 210A, respectively. A single ROI 220 is depicted and described with reference to FIGS. 2A and 2B for simplicity of illustration. Examples depicting horizontal and vertical ROls are described with reference to FIGS. 2C, 2D and 3 below.

The ROI 220 may be associated with an optical or electron micrographic image of the mask. For example, when using image analysis methods to locate a mask overlay mark in an image of the mask, selecting a region of interest 220 can benefit efficiency and accuracy. In some embodiments, a high-resolution image of the mask may be captured, which may include various features and marks, including a depiction of the actual pattern 200A. Instead of processing the entire image, the ROI 220 is selected around an area where the actual pattern 200A is expected to be. The ROI 220 can be a rectangular or other shaped region, and its size can be selected manually or dynamically based on previous marks or layers.

In an operation 20C, within the ROI 220, basic image preprocessing techniques such as noise reduction filters (e.g., Gaussian blur) can be applied to smooth out the image and improve edge detection accuracy. Then, algorithms such as Canny, Sobel or Prewitt may be applied within the ROI 220 to identify edges of the actual pattern 200A. These algorithms may identify areas where a sharp intensity gradient is present, which often corresponds to the boundary of a feature. This is depicted in FIG. 2A by a graph 230, in which an intensity curve 232 includes left- and right-side intensity gradients 232L, 232R that correspond to left- and right-side edges 202L, 202R of the actual pattern 200A. In some embodiments, then, the edge-detected image within the ROI may be subjected to pattern matching algorithms to identify the shape or layout of the overlay mark. In some embodiments, for example, when the actual pattern 200A is known to have a box or square shape, use of pattern matching algorithms may be omitted.

In FIG. 2B, in operation 20D, once the actual pattern 200A is identified, coordinates (e.g., coordinates “(A,B)”) thereof are determined relative to the entire mask image. In one example, for a simple geometry such as a square, the coordinates may be determined based on an equation, such as (Edge1+Edge2)/2, where “Edge1” is a coordinate of a first edge (e.g., the right-side edge 202R) and “Edge2” is a coordinate of a second edge (e.g., the left-side edge 202L). This calculation may be repeated for both the horizontal (e.g., x) coordinate and the vertical (e.g., y) coordinate of the center 210A. The coordinates provide a precise location of the actual pattern 200A, which can be used for alignment or other metrology purposes. Further operations may include refining the edges using morphological operations or using curve fitting to represent the detected edges in mathematical form for more precise measurements. The detected location and shape of the actual pattern 200A may then validated, for example, by matching them against expected or historical data to ensure accuracy.

In operation 20E, a mask overlay offset 240 may be calculated as (A,B)−(x,y). The mask overlay offset 240 may include a horizontal or X-axis offset (e.g., x-A) and a vertical or Y-axis offset (e.g., y-B). The mask overlay offset 240 may be associated with the mask, and may be fed forward to a subsequent process. For example, the mask overlay offset 240 associated with the mask may be fed forward to an exposure process, such that a wafer stage that controls position of a wafer being exposed by a pattern of the mask may offset slightly based on the mask overlay offset 240, so that the pattern is properly aligned relative to underlying layers and/or features that have already been formed.

FIGS. 2C and 2D are diagrammatic views that depict ROIs 220H, 220V as used to detect a large or medium actual pattern 200A (FIG. 2C) and a small actual pattern 200S (FIG. 2D) for the same offset.

In FIG. 2C, because location of the actual pattern 200A is unknown, ROI settings may be selected based on a design layout. Large mask overlay marks (e.g., the actual pattern 200A) have a large tolerance for process error and job settings. The horizontal ROI 220H that is selected fully overlaps the actual pattern 200A in the X-axis direction, and the vertical ROI 220V that is selected fully overlaps the actual pattern 200A in the Y-axis direction. As such, the mask metrology apparatus successfully determines the coordinates (A,B) of the center 210A.

In FIG. 2D, for a small mask overlay mark, tolerance for process errors and job settings may be low. As such, for the same overlay offset or shift, one or both of the ROIs 220H, 220V may not overlap the actual pattern 200S, as depicted. Because the ROIs 220H, 220V do not cover the actual pattern 200S, edges of the actual pattern 200S are not captured, position of a center 210S of the actual pattern 200S is not calculated and measurement fails. This increases difficulty in identifying the small actual patterns 200S, as ROI settings that are improperly tuned may lead to failure in detecting the actual pattern 200S.

FIG. 3 is a diagrammatic view of a designed mask overlay mark 30D and an actual mask overlay mark 30A according to various aspects of the present disclosure. The designed mask overlay mark 30D is associated with dramatically easier ROI settings, which improves detection of the actual mask overlay mark 30A by the mask metrology apparatus 130.

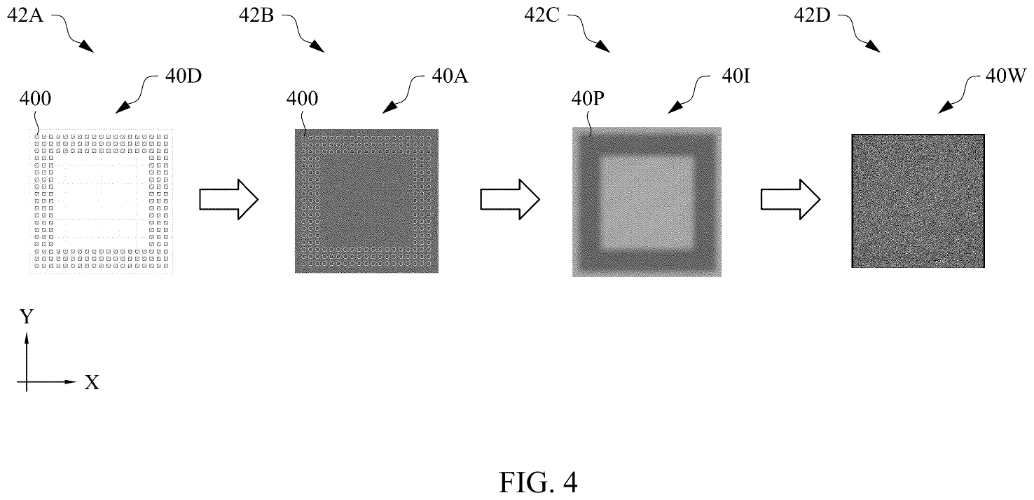

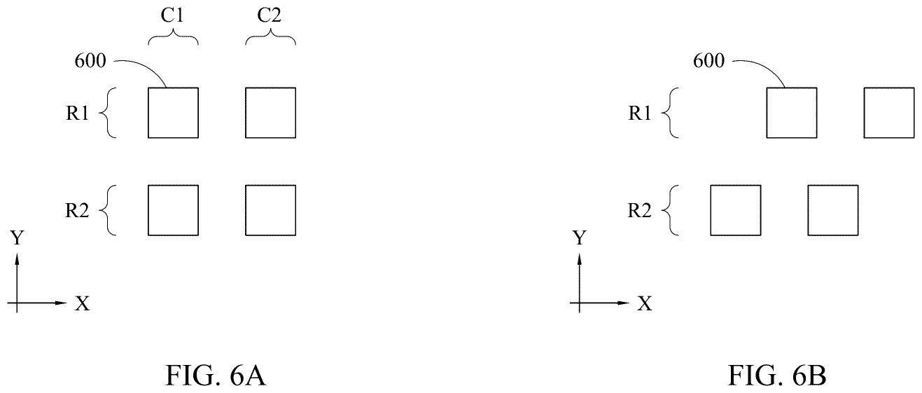

The designed mask overlay mark 30D includes two or more very small overlay patterns 300 that may be arranged in an array, as depicted, or may be arranged in another suitable manner. In the embodiment depicted in FIG. 3, the designed mask overlay mark 30D includes forty-nine overlay patterns 300 that are arranged in a seven-by-seven array. The overlay patterns 300 may be spaced evenly along two axes, such as an X axis and a Y axis, as shown. The overlay patterns 300 may be hollow square patterns. In some embodiments, the overlay patterns 300 are solid or hollow, and may have geometric shape, including, but not limited to, squares, rectangles, triangles, circles, polygons (e.g., hexagons, octagons, or the like), abnormal shapes, combinations thereof, or the like. Example shapes and arrangements of the overlay patterns 300 are described in greater detail with reference to FIGS. 6A-12E. The designed mask overlay mark 30D may have a shape that is an aggregate of the overlay patterns 300, and may itself be substantially solid or hollow, and may have substantially geometric shape, including, but not limited to, squares, rectangles, triangles, circles, polygons (e.g., hexagons, octagons, or the like), abnormal shapes, combinations thereof, or the like. For example, the designed mask overlay mark 30D including hollow square overlay patterns 300 may itself have shape of a square (as depicted), a rectangle, a triangle, another polygon, or the like, which may be “solid” or “hollow.” An example of a “hollow” overlay mark is depicted in FIG. 4 and described with reference thereto.

In FIG. 3, a region 35A of an actual mask overlay mark 30A corresponds to region 35D of the designed mask overlay mark 30D. The overlay patterns 300 are used to form the actual mask overlay mark 30A in a mask. As such, actual overlay patterns 300A in aggregate form the actual mask overlay mark 30A. The actual mask overlay mark 30A is easily detected using horizontal and vertical ROIs 320H, 320V. However, because the actual overlay patterns 300A are smaller than a resolution of the mask metrology apparatus 130 and/or a wafer lithography apparatus (e.g., an EUV step and scan apparatus), the actual overlay patterns 300A are not resolved. As such, the actual overlay patterns 300A are not printed on a wafer being exposed by patterned light formed by the mask. This is described in greater detail with reference to FIG. 4.

FIG. 4 is a sequential view of use of a design mask overlay mark 40D and an actual mask overlay mark 40A according to various aspects of the present disclosure. FIG. 4 depicts various operations or stages 42A, 42B, 42C, 42D of a semiconductor manufacturing process that uses a mask including the mask overlay marks 40D, 40A.

In a first operation 42A, which may be a mask design operation, a design mask overlay mark 40D is selected and/or designed that includes two or more very small overlay patterns or features 400 arranged in a combined shape. The small features 400 may be combined with selected pitch or/and size (e.g., as a hollow square array). For example, the overlay patterns 400 may be combined to form the combined shape that has area in a range of about hundreds of square microns, such as a 20 micron by 20 micron square that has area of 400 square microns. In some embodiments, another suitable shape, such as one of those described with reference to FIG. 3, is used instead of the hollow square shape depicted in FIG. 4. The overlay patterns 400 may be similar in most respects to and/or embodiments of the overlay patterns 300 described with reference to FIG. 3.

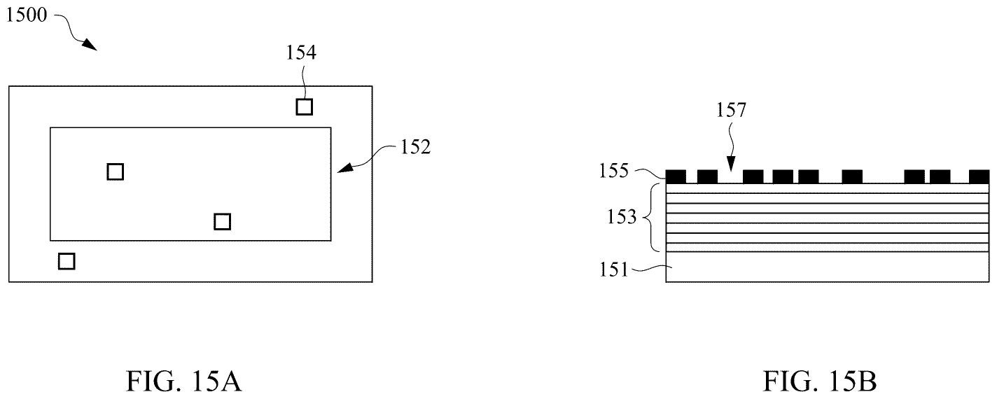

In a second operation 42B, a mask is formed that has actual overlay patterns 400A that are included in an actual mask overlay mark 40A. A mask 150 is depicted in FIGS. 15A and 15B in accordance with various embodiments. The mask 150 may include a substrate 151, which may include a low thermal expansion material to minimize or reduce distortion under a high-energy extreme ultraviolet (EUV) light source. The mask may include a multilayer lattice 153, which may be or include a series of alternating layers of materials like molybdenum (Mo) and silicon (Si) that are deposited on the substrate. The layers can create a Bragg reflector that reflects EUV light efficiently. The mask may include an absorber layer 155 in which an absorber material is applied to the multilayer lattice. The absorber layer may be or include materials like tantalum nitride (TaN) that can effectively absorb EUV light. The mask may include a capping layer (not separately illustrated), which may be a protective layer added to protect the absorber layer and the multilayer lattice from damage, and usually includes a material such as ruthenium (Ru). Initially, a mask blank may be prepared with the substrate and the multilayer coating but without selected patterns formed in the absorber layer.

The actual overlay patterns 400A generally inherit the position, size and shape of the overlay patterns 400 of the designed mask overlay pattern 40D. The individual features 400A are formed well on the mask 150 by a mask-making process and tools. For example, the actual overlay patterns 400A may be formed by one or more writing operations, which may include an electron or ion beam writing operation, an etch operation, another suitable writing operation, or the like. For the high precision beneficial to EUV lithography, electron beam (e-beam) writing is often used to form patterns (e.g., the overlay patterns 400A) on the mask 150. The e-beam is directed to write the design onto a resist layer applied over the absorber layer 155. After e-beam exposure, the mask 150 may be developed, and exposed or unexposed portions of the resist are removed, leaving behind the pattern to be etched (e.g., the overlay patterns 400A) into the absorber layer 155. The pattern is then etched into the absorber layer 155, typically using reactive ion etching (RIE) or a similar technique, revealing the final pattern where the underlying multilayer lattice 153 is exposed by openings 157 in the absorber layer 155. The mask 150 may undergo a series of cleaning and inspection processes to verify whether the mask meets specifications and is free from defects. Any defects found can sometimes be repaired using techniques like focused ion beam (FIB) milling or electron-beam-induced deposition (EBID).

In FIG. 15A, the mask 150 may include a device feature pattern region 152 which includes a plurality of device feature patterns. The mask 150 may include one or more mask overlay marks 154. One or more of the mask overlay marks 154 may be positioned outside and adjacent the device feature pattern region 152. One or more of the mask overlay marks 154 may be positioned inside the device feature pattern region 152, for example, adjacent to one or more of the plurality of device feature patterns.

In a third operation 42C, an image 401 is captured of the mask, which may be a portion of an image of the entire mask or may be an image of a portion of the mask. The image 40I may include a digital representation of the actual mask overlay mark 40A. Individual features (e.g., the actual overlay patterns 400A) may be too small to be resolved by the mask metrology apparatus 130 that captures and/or processes the image, so that contours of the actual overlay patterns 400A are merged as a solid pattern 40P, as depicted in FIG. 4. Edges of the solid pattern 40P may be smoothed, in some embodiments.

In a fourth operation 42D, a pattern of the mask is transferred to a layer of or on a wafer. The pattern may include device feature patterns. Because the actual overlay patterns 400A are very small and may be below a resolution of a wafer imaging tool (e.g., an EUV step and scan apparatus), the actual overlay patterns 400A of the mask are not printed on the wafer by the wafer imaging tool.

In the above, if the designed mask overlay mark 40D does not include the overlay patterns 400, but instead is a solid, continuous pattern, such as a hollow square including solid, continuous lines having thickness similar to that depicted in FIG. 4, the actual mask overlay mark 40A would still be formed well on the mask by the mask making process and tools. In the third operation 42C, the actual mask overlay mark 40A would be detected well by the mask metrology apparatus 130, but may have sharp edges instead of the smooth edges described previously. Then, in the fourth operation 42D, the actual mask overlay mark 40A is transferred to the wafer by the wafer imaging tool. The overlay patterns 400, when included, are beneficial to avoid transferring the actual mask overlay mark 40A to the wafer.

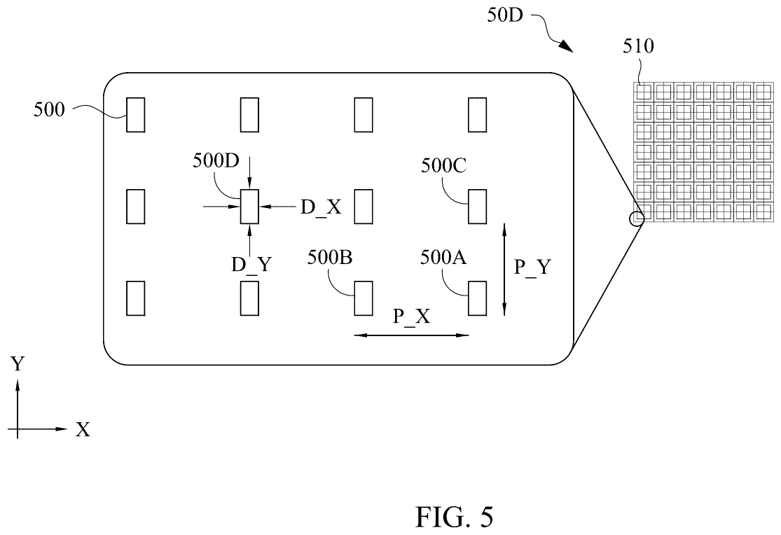

In the above, based on the resolution of the mask metrology apparatus 130, pitch and/or size of the actual overlay patterns 400A and/or the actual mask overlay mark 40A may be selected such that the actual mask overlay mark 40A is not resolved by the mask metrology apparatus 130. Based on configuration of the wafer imaging tool, the pitch and/or size of the actual overlay patterns 400A and/or the actual mask overlay mark 40A may be selected such that the mask overlay mark is not printed on the wafer. For example, dimensions of the overlay patterns 400A (e.g., width or length) can be less than about 100 nm, such that the overlay patterns 400A do not form a pattern on a wafer after an exposure process using the EUV mask. Example dimensions are described briefly below with reference to FIG. 5 for various mask metrology apparatuses 130 and wafer imaging tools.

FIG. 5 is a diagrammatic view depicting in detail a region of a designed mask overlay mark 50D including overlay patterns 500 in accordance with various embodiments. The designed mask overlay mark 50D may be an embodiment of the designed mask overlay mark 30D of FIG. 3. In some embodiments, as depicted, the designed mask overlay mark 50D includes mark features 510, each of which includes overlay patterns 500. The overlay patterns 500 may be embodiments of the overlay patterns 300 of FIG. 3. The mark features 510 may be combinations of the overlay features 500 and a combination of the mark features 510 may be the designed mask overlay mark 50D. The overlay patterns 500, the mark features 510 and the designed mask overlay mark 50D may have different shapes. For example, the overlay patterns 500 may be rectangles, the mark features 510 may be hollow squares and the designed mask overlay mark 50D may be square.

In FIG. 5, the designed mask overlay mark 50D includes overlay patterns 500, which include a first overlay pattern 500A, a second overlay pattern 500B, a third overlay pattern 500C and a fourth overlay pattern 500D.

Size of the overlay patterns 500 is described with reference to the fourth overlay pattern 500D. A first dimension D_X of the fourth overlay pattern 500D may be an X-axis or horizontal dimension. A second dimension D_Y of the fourth overlay pattern 500D may be a Y-axis or vertical dimension. In some embodiments, the first dimension D_X is the same as the second dimension D_Y, such that the fourth overlay pattern 500D has a square shape (or a circular shape, or the like). In some embodiments, the first dimension D_X is different than the second dimension D_Y, such that the fourth overlay pattern 500D has a rectangle shape (or an oval shape, or the like). A size ratio may be a ratio of the first dimension D_X over the second dimension D_Y (e.g., D_X/D_Y) and may be in a range of about 0.1 to about 10, about 0.2 to about 5, about 0.33 to about 3, about 0.5 to about 2, or another suitable range.

Pitch of the overlay patterns 500 is described with reference to the first, second and third overlay patterns 500A, 500B, 500C. A first pitch P_X of the overlay patterns 500 may be an X-axis or horizontal pitch. The first pitch P_X is described with respect to the first and second overlay patterns 500A, 500B. The first pitch P_X may be a distance between the first and second overlay patterns 500A, 500B that are directly adjacent to each other along the horizontal or X-axis direction. The distance may be a distance between corresponding sides or edges of the first and second overlay patterns 500A, 500B. For example, as depicted in FIG. 5, the first pitch P_X may be distance between left edges (relative to the page) of the first and second overlay patterns 500A, 500B.

A second pitch P_Y of the overlay patterns 500 may be an Y-axis or vertical pitch. The second pitch P_Y is described with respect to the first and third overlay patterns 500A, 500C. The second pitch P_Y may be a distance between the first and third overlay patterns 500A, 500C that are directly adjacent to each other along the vertical or Y-axis direction. The distance may be a distance between corresponding sides or edges of the first and third overlay patterns 500A, 500C. For example, as depicted in FIG. 5, the second pitch P_Y may be distance between bottom edges (relative to the page) of the first and third overlay patterns 500A, 500C.

A pitch ratio may refer to a ratio of the first pitch P_X over the second pitch P_Y (e.g., P_X/P_Y), and may be in a range of about 0.1 to about 10, about 0.2 to about 5, about 0.33 to about 3, about 0.5 to about 2, or another suitable range. In some embodiments, the pitch ratio is substantially 1.

The mask metrology apparatus 130 may operate using light having a wavelength and using a selected numerical aperture (NA). The light may be generated by the light source 1350. A half pitch may be referred to as a theoretical resolution or theoretical limit of resolution of the mask metrology apparatus 130, and may be given by the following equation:

$$half pitch = \frac{λ}{2 \cdot ( 1 + σ ) \cdot NA} \geq \frac{λ}{4 \cdot NA}$$

In the above equation, lambda is wavelength, sigma is degree of coherence and NA is numerical aperture. Based on the half pitch or theoretical resolution, the first and/or second pitch P_X, P_Y and/or the first and/or second dimensions D_X, D_Y may be selected to provide the benefits described above with reference to FIGS. 2A-4.

In a first example, wavelength of the light source 1350 may be substantially equal to 266 nm and NA may be substantially equal to 0.8. Under these conditions, the theoretical resolution is about 83 nm. As such, the first and/or second pitch P_X, P_Y may be selected to not exceed about 166 nm (i.e., double the half pitch of 83 nm).

In a second example, the wavelength of the light source 1350 may be substantially equal to 193 nm and NA may be substantially equal to 0.6. Under these conditions, the theoretical resolution is about 80 nm. As such, the first and/or second pitch P_X, P_Y may be selected to not exceed about 160 nm (i.e., double the half pitch of 80 nm).

For mask imaging tools or wafer imaging tools, an EUV light source may be included in the tool, and may generate light having a much shorter wavelength than that of the light source 1350 of the mask metrology apparatus 130. The mask imaging tool may be a tool that is operable to form a mask (e.g., to expose a resist layer on the mask according to a pattern), whereas the mask metrology apparatus 130 is a tool that is operable to analyze the formed mask (e.g., by capturing images thereof and performing image analysis on the images).

In a third example, a wavelength of the EUV light source may be substantially equal to 13.5 nm and NA may be substantially equal to 0.33. Under these conditions, the theoretical resolution of the mask or wafer imaging tool may be substantially 10 nm. As such, the first and/or second pitch P_X, P_Y may be selected to not exceed about 20 nm (i.e., double the half pitch of 10 nm).

In a fourth example, for a wavelength of the EUV light source of 12.3 picometers (pm) and NA equal to 1, the theoretical resolution is much less than 1 nm.

In the above, the described values for the first and/or second pitch P_X, P_Y and/or the first and/or second dimensions D_X, D_Y may be theoretical instead of actual results. In an actual configuration, and in some embodiments, resolution of the mask imaging tool is smaller (e.g., finer) than resolution of the wafer imaging tool, which may be similar to resolution of the mask metrology apparatus 130.

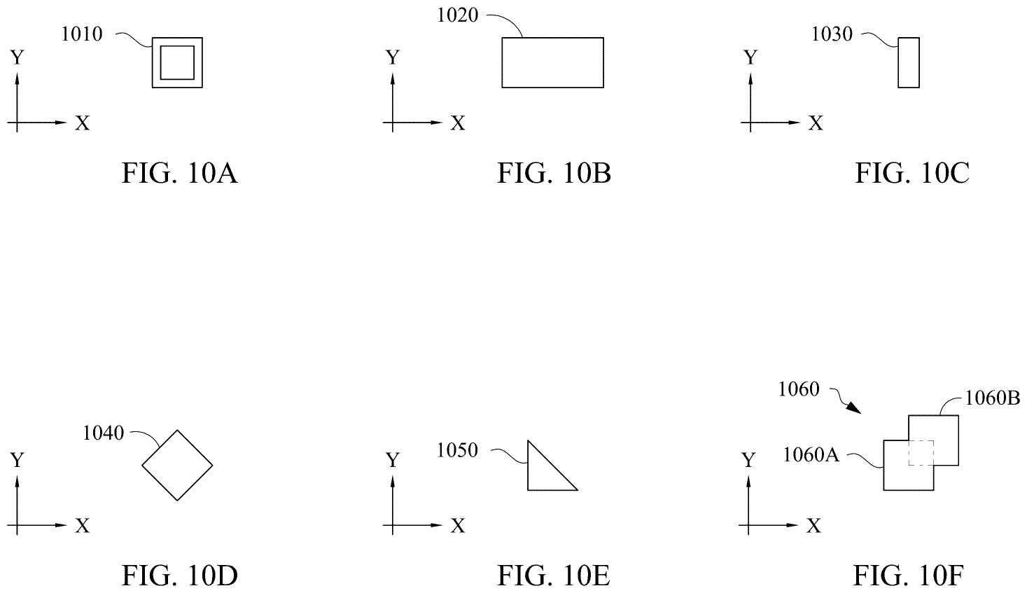

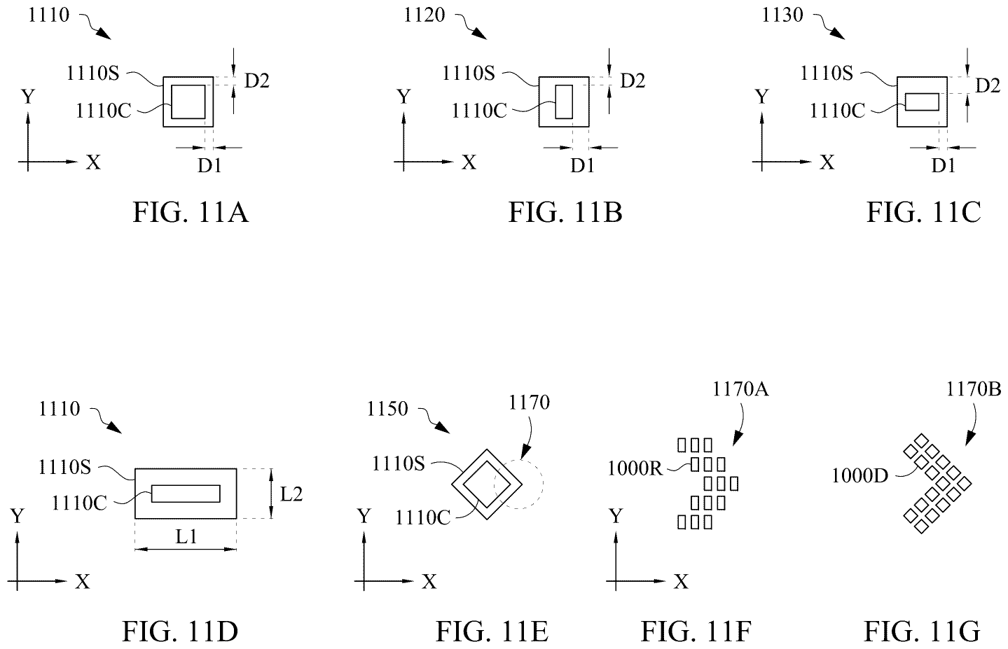

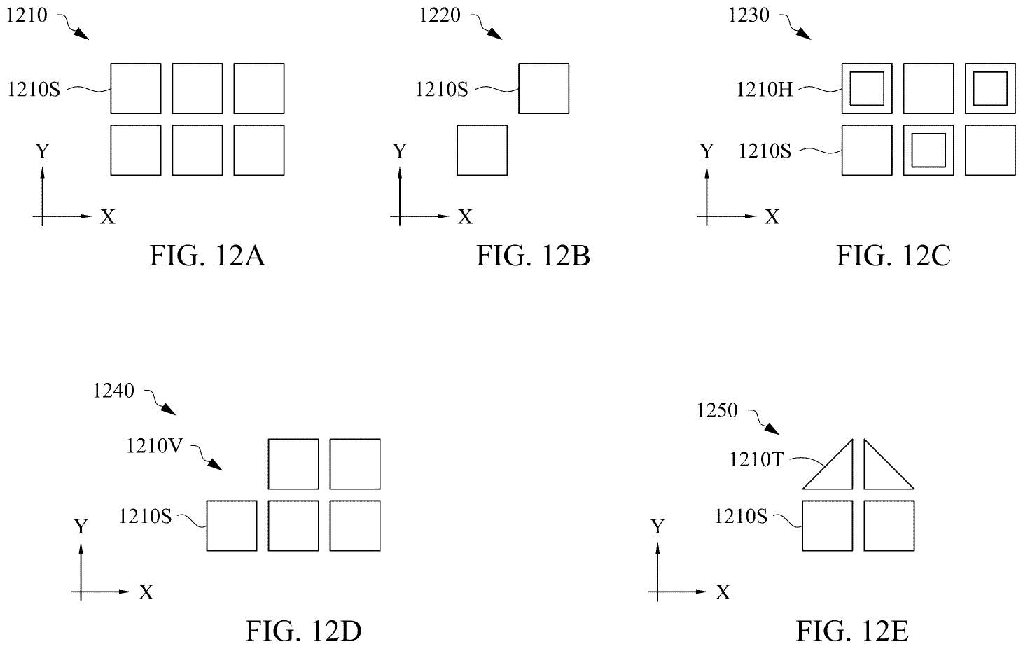

FIGS. 6A-12E are diagrammatic views of overlay patterns and mask overlay marks in accordance with various embodiments. FIGS. 6A-9C are diagrammatic views of overlay patterns. FIGS. 10A-10F are diagrammatic views of individual solid-type mark features. FIGS. 11A-11G are diagrammatic views of individual hollow-type mark features. FIGS. 12A-12E are diagrammatic views of combination mark features.

In FIGS. 6A and 6B, overlay patterns 600 are depicted. The overlay patterns 600 have square shape. Namely, each of the overlay patterns 600 has the same dimension in the X-axis direction (e.g., width) as in the Y-axis direction (e.g., length). Four overlay patterns 600 are depicted in each of FIGS. 6A and 6B. In FIG. 6A, the four overlay patterns 600 are arranged in two rows R1, R2 and two columns C1, C2. Corresponding overlay patterns 600 in each row R1, R2 are aligned to each other and corresponding overlay patterns 600 in each column C1, C2 are aligned to each other. For example, directly adjacent pairs of the overlay patterns 600 are aligned to each other along one direction and offset from each other along another direction. The rows R1, R2 have the same pitch in the Y-axis direction as the columns C1, C2 have in the X-axis direction.

In FIG. 6B, the four overlay patterns 600 are arranged in two rows R1, R2 that are staggered relative to each other, such that adjacent overlay patterns 600 in different, adjacent rows R1, R2 are not arranged in a column but are offset from each other along the X-axis direction.

It should be understood that, although four overlay patterns 600 are depicted in FIGS. 6A and 6B, fewer or more overlay patterns 600 may be included. Although two rows R1, R2 are depicted, a single row or more than two rows may be included. Although two columns C1, C2 are depicted, a single column or more than two columns may be included.

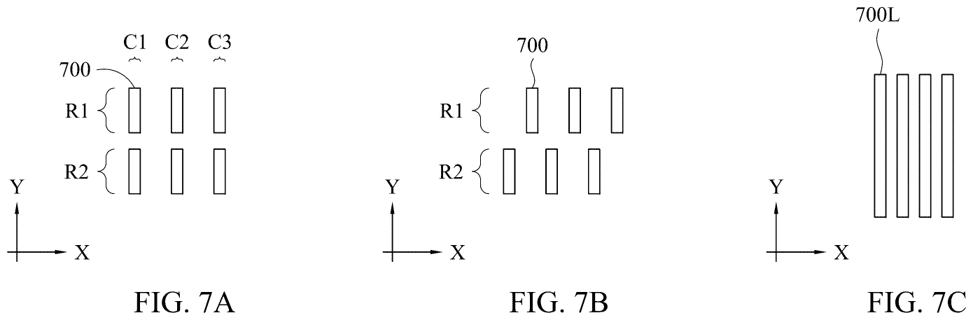

In FIGS. 7A, 7B and 7C, overlay patterns 700 are rectangles that are elongated along the Y-axis direction.

In FIG. 7A, six overlay patterns 700 are arranged in two rows R1, R2 and three columns C1, C2, C3. Corresponding or adjacent overlay patterns 700 of the rows R1, R2 are aligned with each other along a first direction (e.g., the X-axis direction). Corresponding or adjacent overlay patterns 700 of the columns C1, C2, C3 are aligned with each other along a second direction (e.g., the Y-axis direction) that is transverse or perpendicular to the first direction.

In FIG. 7B, the six overlay patterns 700 are arranged in two rows R1, R2, but are staggered relative to each other, such that adjacent overlay patterns 700 in different, adjacent rows R1, R2 are not arranged in a column but are offset from each other along the X-axis direction.

In FIG. 7C, four overlay patterns 700L are arranged side-by-side in the X-axis direction and each extends in the Y-axis direction. The four overlay patterns 700L may each be a line or stripe shape. The line or stripe shape may have aspect ratio (length over width) that exceeds 5, such as about 6, about 7, about 8, about 9, about 10 or more. The rectangle overlay patterns 700 of FIGS. 7A and 7B may have aspect ratio that does not exceed 5 or does not exceed another suitable value. Namely, the rectangle overlay patterns 700 have aspect ratio that exceeds 1 and does not exceed 5 or another suitable value.

It should be understood that, although six overlay patterns 700 are depicted in FIGS. 7A and 7B and four overlay patterns 700L are depicted in FIG. 7C, fewer or more overlay patterns 700, 700L may be included. Although two rows R1, R2 are depicted in FIGS. 7A and 7B, a single row or more than two rows may be included. Although three columns C1, C2, C3 are depicted in FIG. 7A, a single column, two columns or more than three columns may be included.

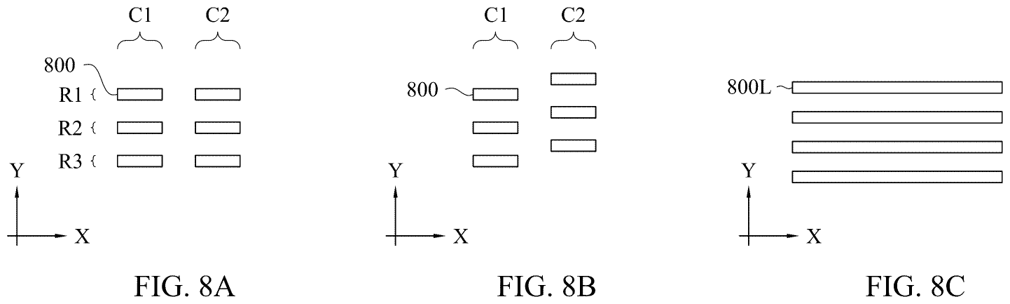

In FIGS. 8A, 8B and 8C, overlay patterns 800 are rectangles that are elongated along the X-axis direction.

In FIG. 8A, six overlay patterns 800 are arranged in three rows R1, R2, R3 and two columns C1, C2. Corresponding or adjacent overlay patterns 800 of the rows R1, R2, R3 are aligned with each other along a first direction (e.g., the X-axis direction). Corresponding or adjacent overlay patterns 800 of the columns C1, C2 are aligned with each other along a second direction (e.g., the Y-axis direction) that is transverse or perpendicular to the first direction.

In FIG. 8B, the six overlay patterns 800 are arranged in two columns C1, C2, but are staggered relative to each other, such that adjacent overlay patterns 800 in different, adjacent columns C1, C2 are not arranged in a row but are offset from each other along the Y-axis direction.

In FIG. 8C, four overlay patterns 800L are arranged side-by-side in the Y-axis direction and each extends in the X-axis direction. The four overlay patterns 800L may each be a line or stripe shape. The line or stripe shape may have aspect ratio (length over width) that exceeds 5, such as about 6, about 7, about 8, about 9, about 10 or more. The rectangle overlay patterns 800 of FIGS. 8A and 8B may have aspect ratio that does not exceed 5 or does not exceed another suitable value. Namely, the rectangle overlay patterns 800 have aspect ratio that exceeds 1 and does not exceed 5 or another suitable value.

It should be understood that, although six overlay patterns 800 are depicted in FIGS. 8A and 8B and four overlay patterns 800L are depicted in FIG. 8C, fewer or more overlay patterns 800, 800L may be included. Although three rows R1, R2, R3 are depicted in FIG. 8A, a single row, two rows or more than three rows may be included. Although two columns C1, C2 are depicted in FIGS. 8A and 8B, a single column or more than two columns may be included.

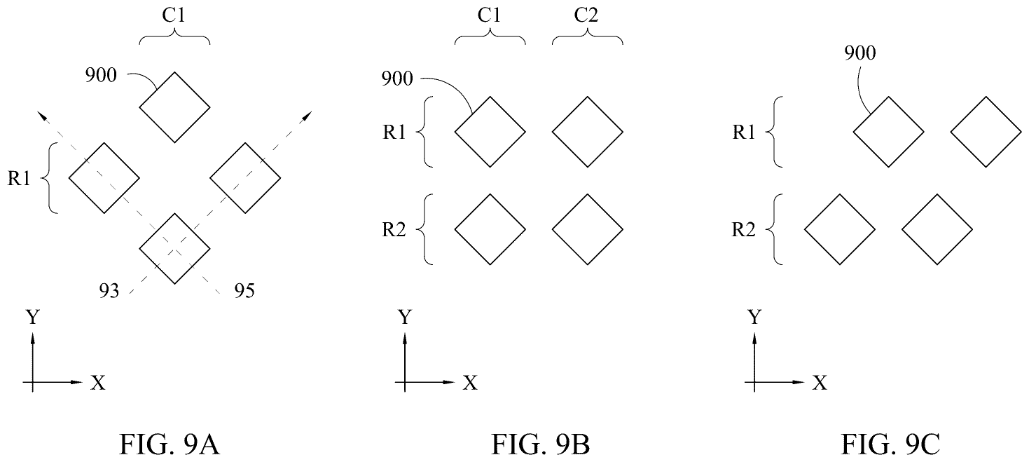

In FIGS. 9A, 9B and 9C, four overlay patterns 900 are depicted. Each of the overlay patterns 900 has diamond shape, which may be a square shape that is rotated 45 degrees relative to the X and Y axes.

In FIG. 9A, directly adjacent pairs of the overlay patterns 900 are aligned with each other along one of two single directions 93, 95, which may be directions 93, 95 that are rotated 45 degrees or 135 degrees from the X axis, respectively. Two of the overlay patterns 900 may be arranged in a row R1, and another two of the overlay patterns 900 may be arranged in a column C1, as shown.

In FIG. 9B, four diamond-shaped overlay patterns 900 are arranged in two rows R1, R2 and two columns C1, C2. The two rows R1, R2 extend along the X-axis direction and the two columns C1, C2 extend along the Y-axis direction. The overlay patterns 900 in the same row are aligned with each other. The overlay patterns 900 in the same column are aligned with each other.

In FIG. 9C, four diamond-shaped overlay patterns 900 are arranged in two rows R1, R2, but the two rows R1, R2 are staggered, such that the overlay patterns 900 are not arranged in columns. Namely, the overlay patterns 900 in the same row are aligned with each other, but in the Y-axis direction, directly adjacent overlay patterns 900 are not aligned with each other.

It should be understood that, although four overlay patterns 900 are depicted in FIGS. 9A, 9B and 9C, fewer or more overlay patterns 900 may be included. Although a single row R1 is depicted in FIG. 9A and two rows R1, R2 are depicted in FIGS. 9B and 9C, fewer or additional rows may be included. Although a single column C1 is depicted in FIG. 9A and two columns C1, C2 are depicted in FIG. 9B, fewer or additional columns may be included.

FIGS. 10A-10F are diagrammatic views of individual solid-type mark features 1010, 1020, 1030, 1040, 1050, 1060. Each of the mark features 1010, 1020, 1030, 1040, 1050, 1060 may include a plurality of the overlay patterns described with reference to FIGS. 6A-9C, which may be arranged in an array or other suitable arrangement. Individual overlay patterns are not depicted in FIGS. 10A-10F for simplicity of illustration. Embodiments of overlay patterns included in a mark feature are illustrated in FIGS. 11E, 11F, 11G.

In FIG. 10A, a mark feature 1010 may be a square mark feature that has the same dimension in the X-axis direction as in the Y-axis direction. The mark feature 1010 may include any of the overlay patterns described with reference to FIGS. 6A-9C. For example, the mark feature 1010 may include an array of square overlay patterns, such as is depicted in FIGS. 6A and 6B, any of the rectangle or line/stripe overlay patterns depicted in FIGS. 7A-8C, any of the diamond overlay patterns depicted in FIGS. 9A-9C, combinations thereof, or the like.

In FIG. 10B, a mark feature 1020 may be a rectangular mark feature that has dimension in the X-axis direction that exceeds dimension in the Y-axis direction. The mark feature 1020 may include any of the overlay patterns described with reference to FIGS. 6A-9C. For example, the mark feature 1020 may include an array of square overlay patterns, such as is depicted in FIGS. 6A and 6B, any of the rectangle or line/stripe overlay patterns depicted in FIGS. 7A-8C, any of the diamond overlay patterns depicted in FIGS. 9A-9C, combinations thereof, or the like.

In FIG. 10C, a mark feature 1030 may be a rectangular mark feature that has dimension in the Y-axis direction that exceeds dimension in the X-axis direction. The mark feature 1030 may include any of the overlay patterns described with reference to FIGS. 6A-9C. For example, the mark feature 1020 may include an array of square overlay patterns, such as is depicted in FIGS. 6A and 6B, any of the rectangle or line/stripe overlay patterns depicted in FIGS. 7A-8C, any of the diamond overlay patterns depicted in FIGS. 9A-9C, combinations thereof, or the like.

In FIG. 10D, a mark feature 1040 may be a diamond mark feature that has width that is equal to length thereof. The mark feature 1040 may include any of the overlay patterns described with reference to FIGS. 6A-9C. For example, the mark feature 1040 may include an array of square overlay patterns, such as is depicted in FIGS. 6A and 6B, any of the rectangle or line/stripe overlay patterns depicted in FIGS. 7A-8C, any of the diamond overlay patterns depicted in FIGS. 9A-9C, combinations thereof, or the like.

In FIG. 10E, a mark feature 1050 may be a triangle mark feature that has dimension in the X-axis direction that is equal to dimension thereof in the Y-axis direction. In some embodiments, the X-axis dimension may be different than the Y-axis dimension. The triangle of FIG. 10E is depicted as a right triangle. In some embodiments, other triangles (e.g., isosceles, equilateral, scalene, obtuse, acute, or the like) may be the shape of the mark feature 1050 instead of the right triangle shown. The mark feature 1050 may include any of the overlay patterns described with reference to FIGS. 6A-9C. For example, the mark feature 1050 may include an array of square overlay patterns, such as is depicted in FIGS. 6A and 6B, any of the rectangle or line/stripe overlay patterns depicted in FIGS. 7A-8C, any of the diamond overlay patterns depicted in FIGS. 9A-9C, combinations thereof, or the like.

In FIG. 10F, a mark feature 1060 may have irregular shape. For example, the mark feature 1060 depicted in FIG. 10F has eight sides and may include two square or rectangle shapes that overlap each other. A first square shape 1060A is overlapped by a second square shape 1060B, which are depicted by different hashed lines in FIG. 10F. The mark feature 1060 may include any of the overlay patterns described with reference to FIGS. 6A-9C. For example, the mark feature 1060 may include an array of square overlay patterns, such as is depicted in FIGS. 6A and 6B, any of the rectangle or line/stripe overlay patterns depicted in FIGS. 7A-8C, any of the diamond overlay patterns depicted in FIGS. 9A-9C, combinations thereof, or the like.

FIGS. 11A-11G are diagrammatic views of individual hollow-type mark features. FIGS. 11A-11E depict hollow-type mark features 1110, 1120, 1130, 1140, 1150 and FIGS. 11F and 11G are detailed views of a region 1170 of FIG. 11E.

In FIG. 11A, the mark feature 1110 is a hollow square shape, which can include a solid region 1110S and a cutout region 1110C. It should be understood that “cutout” does not require an action of cutting, but refers to an absence of overlay patterns in the cutout region 1110C which gives the appearance of a cutout from the square-shaped solid region 1110S. The cutout region 1110C may also be referred to as a blank region, void region, or the like. The solid region 1110S may be a continuous region that includes overlay patterns therein. The solid region 1110S may surround the cutout region 1110C on four sides. The solid region 1110S may include vertically-extended portions having width D1 and horizontally-extended portions having width D2. In some embodiments, as depicted in FIG. 11A, the width D1 is equal to or substantially equal to the width D2.

The solid region 1110S may include the overlay patterns therein, and an area ratio of the overlay patterns as a portion of total area of the solid region 1110S may exceed about 30%, about 40%, about 50% or another suitable percentage. The overlay patterns in the solid region 1110S may be distributed substantially evenly (or uniformly). In some embodiments, the overlay patterns in the solid region 1110S are distributed randomly or pseudo-randomly. For example, each of the overlay patterns in the solid region 1110S may be separated from directly adjacent others of the overlay patterns by a dimension within a range, such as between a first dimension and a second dimension larger than the first dimension. For example, the first dimension may be about 150 nm (e.g., 160 nm, 166 nm, or the like) and the second dimension may exceed about 200 nm (e.g., 200 nm, 250 nm, 300 nm, or the like). The first dimension and the second dimension may have other values in some embodiments.

In FIG. 11B, the mark feature 1120 is a hollow square shape that is similar in many respects to the mark feature 1110 of FIG. 11A. In the mark feature 1120, the width D1 of the vertically-extended portions exceeds the width D2 of the horizontally-extended portions.

In FIG. 11C, the mark feature 1130 is a hollow square shape that is similar in many respects to the mark feature 1110 of FIG. 11A. In the mark feature 1130, the width D2 of the horizontally-extended portions exceeds the width D1 of the vertically-extended portions.

In FIG. 11D, the mark feature 1140 is a hollow rectangle shape that is similar in many respects to the mark feature 1110 of FIG. 11A. In the mark feature 1140, length L1 of the horizontally-extended portions exceeds length L2 of the vertically-extended portions. While not separately depicted, in some embodiments, the length L2 of the vertically-extended portions may exceed the length L1 of the horizontally-extended portions. In the embodiments described with reference to FIG. 11D, the widths D1, D2 may be the same as each other or different than each other.

In FIG. 11E, the mark feature 1150 is a hollow diamond shape that is similar in many respects to the mark feature 1110 of FIG. 11A. The mark feature 1150 may be a hollow square shape that is rotated 45 degrees relative to the X axis or the Y axis, as shown. In some embodiments, any of the mark features described with reference to FIGS. 11A-11D may be rotated 45 degrees to form a hollow diamond shape having somewhat different dimensions than the mark feature 1150 depicted in FIG. 11E. The solid region 1110S of the mark feature 1150 is diamond shaped, and the cutout region 1110C of the mark feature 1150 is diamond shaped. A corner region 1170 is highlighted in FIG. 11E in phantom and detailed views of embodiments thereof are depicted in FIGS. 11F and 11G.

FIG. 11F is a detailed view of a corner region 1170A that is an embodiment of the corner region 1170 of FIG. 11E. In the corner region 1170A, overlay patterns 1000R that are rectangles are arranged as shown. The solid region 1110S of the mark feature 1150 may include three concentric rings (e.g., concentric diamonds) of rectangular overlay patterns 1000R. FIG. 11F depicts five adjacent rows and five adjacent columns of the overlay patterns 1000R. In some embodiments, the mark feature 1150 includes fewer or additional concentric diamonds of rectangular overlay patterns 1000R than the three depicted in FIG. 11F.

FIG. 11G is a detailed view of a corner region 1170B that is an embodiment of the corner region 1170 of FIG. 11E. In the corner region 1170B, overlay patterns 1000D that are diamonds are arranged as shown (e.g., similar to that shown in FIG. 9A). The diamond-shaped overlay patterns 1000D may be arranged in two concentric diamonds. In some embodiments, the mark feature 1150 includes fewer or additional concentric diamonds of diamond-shaped overlay patterns 1000D than the two depicted in FIG. 11G.

It should be understood that, in some embodiments, any of the overlay patterns and arrangements thereof described with reference to FIGS. 6A-9C may be included individually or in combination in the mark features 1110, 1120, 1130, 1140, 1150 of FIGS. 11A-11E.

FIGS. 12A-12E are diagrammatic views of combination mark features 1210, 1220, 1230, 1240, 1250. The combination mark features 1210, 1220, 1230, 1240, 1250 may include a combination of two or more individual mark features, such as those described with reference to FIGS. 10A-11G.

In FIG. 12A, the combination mark feature 1210 includes two or more (e.g., six) square mark features 1210S, which may be similar in most respects to the mark feature 1010 described with reference to FIG. 10A. The mark features 1210S may be arranged in rows and columns that are aligned with each other. For example, six mark features 1210S arranged in two rows and three columns are depicted in FIG. 12A. The combination mark feature 1210 may include fewer or additional mark features 1210S compared to those depicted in FIG. 12A.

In FIG. 12B, the combination mark feature 1220 includes square mark features 1210S that are arranged in a staggered arrangement. Namely, two square mark features 1210S may be offset from each other in the Y-axis direction and may partially overlap or not overlap along the X-axis direction. FIG. 12B depicts an embodiment in which the two square mark features 1210S partially overlap along the X-axis direction. The combination mark feature 1220 may include fewer or additional mark features 1210S compared to those depicted in FIG. 12B.

In FIG. 12C, the combination mark feature 1230 includes square mark features 1210S and hollow square mark features 1210H. In some embodiments, the mark features 1210S, 1210H are arranged alternately in an array as shown. For example, square mark features 1210S may have one or more hollow square mark features 1210H directly adjacent thereto along the X-axis direction and/or the Y-axis direction. The mark features 1210S, 1210H may be arranged in rows and columns as depicted in FIG. 12C similar to FIG. 12A. In some embodiments, the mark features 1210S, 1210H may have a staggered arrangement similar to FIG. 12B. The combination mark feature 1230 may include fewer or additional mark features 1210S, 1210H compared to those depicted in FIG. 12C.

In FIG. 12D, the combination mark feature 1240 may be similar in most respects to the combination mark feature 1210 described with reference to FIG. 12A. In the combination mark feature 1240, one or more of the square mark features 1210S may be replaced with a void feature 1210V. Namely, in the void feature 1210V, no overlay patterns are present. Said another way, one or more of the square mark features 1210S may be omitted. The combination mark feature 1230 may include fewer or additional mark features 1210S compared to those depicted in FIG. 12D. The combination mark feature 1230 may include one or more hollow mark features, such as the hollow square mark features 1210H of FIG. 12C, in some embodiments.

In FIG. 12E, the combination mark feature 1250 may be similar in some respects to the combination mark features 1210, 1230, 1240. The combination mark feature 1250 includes a row of triangle mark features 1210T and a row of square mark features 1210S directly adjacent thereto in the Y-axis direction. The triangle mark features 1210T may be symmetrical around the Y axis, as shown. In some embodiments, the triangle mark features 1210T may be asymmetrical around the Y axis. The triangle mark features 1210T may be aligned with the square mark features 1210S along the X-axis direction. The triangle mark features 1210T may be any of the triangles described with reference to FIG. 10E.

In FIGS. 6A-12E, the actual mask overlay mark, which may include any of the mark features or combination mark features described with reference to FIGS. 10A-12E, is large enough to be resolved by the mask metrology apparatus 130 for performing alignment correction of the EUV mask. However, because the overlay patterns have dimensions and/or pitch that are well below a resolution of the mask metrology apparatus, the individual overlay patterns are not resolved by the mask metrology apparatus 130. And, the pitch or/and size of the overlay patterns is sufficiently small, such that the actual mask overlay mark is not printed on the wafer. The size and/or pitch of the overlay patterns may be less than about 100 nm, in some embodiments, such that the overlay patterns do not form a pattern on the wafer after an exposure process using the EUV mask including the actual mask overlay mark.

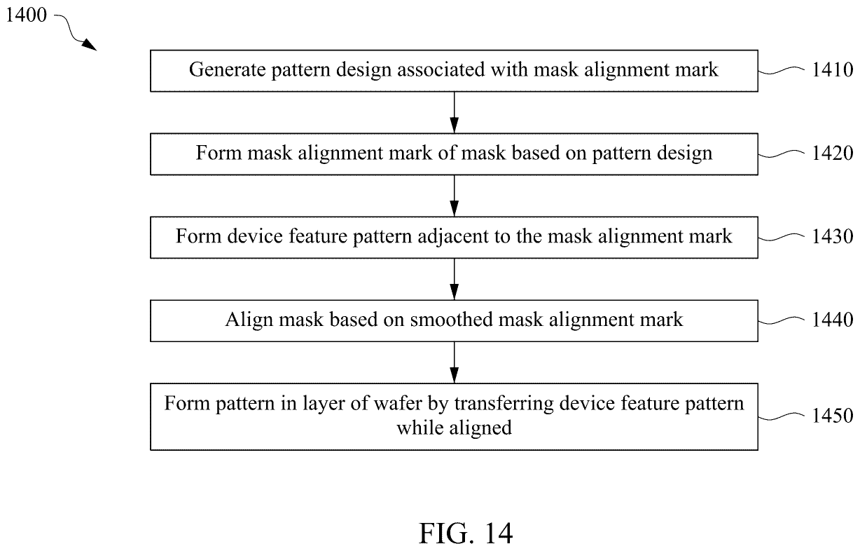

FIG. 14 is a flowchart of a method of forming an IC device in accordance with various embodiments. FIG. 14 illustrates a flowchart of method 1400 for forming an IC device or a portion thereof from a workpiece, according to one or more aspects of the present disclosure. Method 1400 is merely an example and is not intended to limit the present disclosure to what is explicitly illustrated in method 1400. Additional acts can be provided before, during and after the method 1400 and some acts described can be replaced, eliminated, or moved around for additional embodiments of the method. Not all acts are described herein in detail for reasons of simplicity.

The method 1400 begins with operation 1410, in which a pattern design is generated that is associated with a mask overlay mark. The pattern design may be one of the designed mask overlay marks described previously with reference to FIGS. 2A-5. The designed mask overlay mark may include one or more mask features, such as those described with reference to FIGS. 10A-11G. Each of the mask features may include one or more overlay patterns, such as those described with reference to FIGS. 6A-9C. Size of the designed mask overlay mark may be large enough to be resolved by the mask metrology apparatus 130. Size of the overlay patterns may be small enough to not be printed to a wafer by an EUV scanner having the mask including the mask overlay mark therein.

Operation 1420 follows operation 1410. In operation 1420, following generation of a pattern design associated with a mask overlay mark, the mask overlay mark is formed in a mask based on the pattern design. For example, the actual mask overlay mark described with reference to FIGS. 2A-5 is printed onto the mask using any of the methods described with reference to FIG. 4. For example, the actual mask overlay mark may be formed on the mask by removing portions of an absorber layer over a multilayer lattice or reflector via an electron beam or etching based on the designed mask overlay mark. In most embodiments, more than one actual mask overlay mark is formed in operation 1420, and the various actual mask overlay marks may be distributed at selected locations across the surface of the mask.

Operation 1430 is generally performed simultaneously with operation 1420. In operation 1430, while forming the actual mask overlay mark in the mask, a device feature pattern is formed in the mask adjacent to the actual mask overlay mark. The device feature pattern may at least include a plurality of patterns that correspond to device features (e.g., contacts, vias, traces, epitaxial regions, openings, grooves, holes, or the like) to be printed to one or more circuit regions of the wafer. The mask may be completed following operations 1420 and 1430. Additional operations, such as an inspection operation and/or a repair operation may be performed following operations 1420, 1430 and prior to operation 1440.

Operation 1440 follows operation 1430. In operation 1440, alignment associated with the mask is performed based on the actual mask overlay mark. The alignment in operation 1440 may be performed by the mask metrology apparatus 130. Because the overlay patterns are below a resolution of the mask metrology apparatus 130, the alignment may be performed based on the actual mask overlay mark that is smoothed in a digital image captured by the mask metrology apparatus 130. The actual mask overlay mark being “smoothed” includes the meaning that one or more edges thereof in the digital image are smooth instead of sharp, due to the overlay patterns not being resolved by the mask metrology apparatus 130.

Operation 1440 may include one or more operations. For example, operation 1440 may include an initial alignment. Prior to a lithographic exposure process, the actual mask overlay mark(s) on the mask may be used to obtain an initial coarse alignment with corresponding marks on the wafer. Then, a fine alignment operation may be performed. For example, the mask metrology apparatus 130 may capture one or more images of the actual mask overlay marks. The images are then analyzed to compute alignment errors, allowing for precise adjustments. The operation 1440 may include stage synchronization, in which the actual mask overlay marks are used to synchronize a mask stage with a wafer stage, which may be moving in synchronization for step-and-scan lithographic processes. In some embodiments, the operation 1440 includes reticle correction, in which the alignment marks can serve as reference points for any real-time corrections needed to adjust for mask distortions.

In some embodiments, operation 1440 includes one or more other processes that will be described herein. In operation 1440, a high-resolution imaging system, which may utilize low-wavelength light sources or electron beams, captures detailed images of the mask, including the actual mask overlay marks. Advanced software algorithms can analyze the images to locate the edges of the actual mask overlay mark(s) accurately. Dimension metrology tools may be used to measure dimensions of the actual mask overlay mark(s), for example, to determine whether they are within selected tolerances. Metrology equipment, such as the mask metrology apparatus 130, can measure the position(s) of the actual mask overlay mark(s) relative to other features on the mask or relative to intended design coordinates. Operation 1440 may include verifying that the actual mask overlay marks are precisely where they should be according to design specifications. Accuracy in the position(s) of the actual mask overlay mark(s) and measurements thereof are beneficial to calibrate mask alignment systems in lithography tools, so that proper alignment is provided during a wafer exposure process. Consistency in the positioning of the actual mask overlay mark(s) is beneficial for maintaining a high yield in manufacturing of semiconductor wafers. In some embodiments, in operation 1440, real-time adjustments may be made, in which data from mask metrology can be fed back in real-time to correct any discrepancies during mask fabrication. The metrology data can also be used in feed-forward systems to anticipate and correct potential errors in subsequent manufacturing steps. Long-term metrology data can help in identifying trends or recurring issues, allowing for preventive maintenance and process improvements. When small, consistent errors are detected, dynamic corrections can be applied during the lithography process to compensate for these known errors, thereby improving overlay accuracy.

Operation 1440 may include reticle fingerprinting, in which a ‘fingerprint’ of the mask's characteristics is formed based on metrology data, which can then be used for more accurate alignment during the lithography process. The fingerprint may include positions of the actual mask overlay marks.

Operation 1450 follows operation 1440. In operation 1450, with the mask installed in a photolithography apparatus, such as an EUV scanner, the device feature pattern is transferred to the wafer to form a pattern in a layer of the wafer. Transfer of the device feature pattern may be performed under alignment based on the actual mask overlay mark(s). For example, EUV light may be directed to the mask and reflect from the device feature pattern. The reflected light may then be incident directly or indirectly onto the layer of the wafer, which may be a photoresist layer.

Additional operations may follow operation 1450. For example, following exposure of the photoresist layer, exposed or unexposed portions of the photoresist layer may be removed to expose an underlying material layer of the wafer. The underlying material layer may then be etched through the patterned photoresist layer to form openings in the underlying material layer. Device features, such as epitaxial features, dielectric layers, conductive layer, or the like, may be formed in the openings.

Embodiments may provide advantages. Using small overlay patterns with selected range of pitch and/or pitch/size combination as a mask overlay mark improves mask overlay reliability and repeatability performance while providing robust mask overlay measurement on the mask and not printing the mask overlay mark pattern to the wafer.

In accordance with at least one embodiment, a method includes: generating a designed mask overlay mark associated with an actual mask overlay mark to be formed in a mask; forming the actual mask overlay mark in the mask based on the designed mask overlay mark, the actual mask overlay mark including a plurality of overlay patterns; forming a device feature pattern adjacent to the actual mask overlay mark; forming an alignment of the mask by a mask metrology apparatus including a light source having a wavelength and a numerical aperture, wherein a pitch between adjacent two of the plurality of overlay patterns does not exceed the wavelength divided by twice the numerical aperture; and forming a pattern in a layer of a wafer by transferring the device feature pattern while the mask is under the alignment.

In accordance with at least one embodiment, a method includes: forming an actual mask overlay mark in a mask based on a designed mask overlay mark, the actual mask overlay mark including a plurality of overlay patterns, no dimension of each of the plurality of overlay patterns exceeding about a first wavelength over twice a first numerical aperture, the first wavelength and the first numerical aperture being associated with a first light source of a lithography scanner; determining an overlay offset between the actual mask overlay mark and the designed mask overlay mark by a mask metrology apparatus that includes a second light source having a second wavelength and a second numerical aperture, wherein a pitch between adjacent two of the plurality of overlay patterns does not exceed the second wavelength divided by twice the second numerical aperture; forming patterned light by reflecting light of the first light source by the mask; forming a patterned layer of a wafer including exposing a layer to the patterned light without exposing the layer to a pattern of the actual mask overlay mark; and patterning a layer underneath the patterned layer through openings in the patterned layer.

In accordance with at least one embodiment, a device includes: a device feature pattern; and a mask overlay mark adjacent the device feature pattern, the mask overlay mark including a plurality of overlay patterns, wherein from a top view: each of the plurality of overlay patterns has no dimension that exceeds about 100 nanometers (nm); and a first pitch between an adjacent two of the plurality of overlay patterns is less than about 2×(λ/(4·NA)), λ being a wavelength of a measuring light of a mask metrology apparatus and NA being a numerical aperture of the measuring light.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A mask, comprising:
a device feature pattern; and
a mask overlay mark adjacent the device feature pattern, the mask overlay mark including an array of overlay patterns, wherein from a top view:
each of the plurality of overlay patterns has no dimension that exceeds about 100 nanometers (nm); and
a first pitch between an adjacent two of the plurality of overlay patterns is less than about 2×(λ/(4·NA)), λ being a wavelength of a measuring light of a mask metrology apparatus and NA being a numerical aperture of the measuring light.

2. The mask of claim 1, wherein the plurality of overlay patterns is arranged having the first pitch along a first direction and a second pitch along a second direction that is transverse the first direction.

3. The mask of claim 2, wherein the first pitch is different than the second pitch.

4. The mask of claim 2, wherein the first pitch and the second pitch each do not exceed a resolution of the mask metrology apparatus.

5. The mask of claim 4, wherein the resolution is about 160 nm.

6. The mask of claim 1, wherein the array of overlay patterns includes:
a first row of first overlay patterns; and
a second row of second overlay patterns.

7. The mask of claim 6, wherein:
the first overlay patterns have a rectangular shape; and
the second overlay patterns have the rectangular shape.

8. The mask of claim 7, wherein the first row of first overlay patterns and the second row of second overlay patterns define:
a first column of respective overlay patterns including at least one of the first overlay patterns and at least one of the second overlay patterns; and
a second column of respective overlay patterns including at least one of the first overlay patterns and at least one of the second overlay patterns.

9. The mask of claim 6, wherein the first overlay patterns are offset relative to the second overlay patterns.

10. The mask of claim 1, wherein the array of overlay patterns includes:
a first column of first overlay patterns; and
a second column of second overlay patterns.

11. The mask of claim 10, wherein the first overlay patterns of the first column are offset from the second overlay patterns of the second column.

12. The mask of claim 11, wherein the first overlay patterns and the second overlay patterns have a rectangular shape.

13. The mask of claim 1, wherein the array of overlay patterns are rectangular and define a row.

14. The mask of claim 1, wherein the array of overlay patterns are rectangular and define a column.

15. A mask, comprising:
a device feature pattern; and
a mask overlay mark adjacent the device feature pattern, the mask overlay mark including an array of overlay patterns having a diamond shape, wherein from a top view:
each of the plurality of overlay patterns has no dimension that exceeds about 100 nanometers (nm); and
a first pitch between an adjacent two of the plurality of overlay patterns is less than about 2×(λ/(4·NA)), λ being a wavelength of a measuring light of a mask metrology apparatus and NA being a numerical aperture of the measuring light.

16. The mask of claim 15, wherein the array of overlay patterns having the diamond shape include:
a first group of the diamond shape overlay patterns defining a first row; and
a second group if the diamond shape overlay patterns defining a second row.

17. The mask of claim 15, wherein the first row of the first group of the diamond shape overlay patterns and the second row of the second group of the overlay patterns define:
a first column including at least one of the first group of the diamond shape overlay patterns and at least one of the second group of the diamond shape overlay patterns; and
a second column including at least one of the first group of the diamond shape overlay patterns and at least one of the second group of the diamond shape overlay patterns.

18. The mask of claim 15, wherein the first group of the diamond shape overlay patterns defining the first row are offset from the second group of the diamond shape overlay patterns defining the second row.

19. A mask, comprising:
a device feature pattern; and
a mask overlay mark adjacent the device feature pattern, the mask overlay mark including an array of overlay patterns including a row of triangle overlay patterns and a row of square mark patterns, wherein from a top view:
each of the plurality of overlay patterns has no dimension that exceeds about 100 nanometers (nm); and
a first pitch between an adjacent two of the plurality of overlay patterns is less than about 2×(λ/(4·NA)), λ being a wavelength of a measuring light of a mask metrology apparatus and NA being a numerical aperture of the measuring light.

20. The mask of claim 19, wherein each respective triangle overlay pattern is aligned with a corresponding square overlay patterns.
